(19) United States
(12) Patent Application Publication
(10) Pub. No.: US 2021/0213662 A1
(43) Pub. Date: Jul. 15, 2021

(54) METHOD FOR CONTROLLING A MACHINE FOR PROCESSING PLASTICS

(71) Applicant: ARBURG GMBH + CO KG, Loßburg (DE)

(72) Inventors: Eberhard DUFFNER, Starzach (DE); Herbert KRAIBÜHLER, Loßburg (DE)

(21) Appl. No.: 17/268,155

(22) PCT Filed: Sep. 19, 2019
(86) PCT No.: PCT/EP2019/075142

§ 371 Date: Feb. 12, 2021

(30) Foreign Application Priority Data
Sep. 23, 2018 (DE) 10 2018 123 361.2

(51) Int. Cl. B29C 45/76; G06F 30/20

(52) U.S. Cl. CPC B29C 45/766; G06F 30/20; B29C 2945/76056; B29C 2945/76107; B29C 2945/76946

(57) ABSTRACT

The invention relates to a method that serves to control a machine (10) for processing plastics and other plasticisable materials such as powdered and/or ceramic substances. The machine has a mould opening and closing unit (12) for opening and closing an injection mould (14) having at least one mould cavity (16) for producing an injection moulded part (18) corresponding to the shape of the mould cavity (16), an injection moulding unit (20) having means for plasticising and for injection of the plasticisable material in the mould cavity (16) and has a machine control (22) which is connected to an expert knowledge source (34) and if required can be operated by the operator by means of an interactive contact. Information concerning the geometry of the injection moulded part (18) and/or the mould cavity (16) and the sprue geometry (24) are provided to the machine control (22), in order to calculate at least one injection process taking the geometric information into consideration. Because an injection process is calculated, taking into consideration the geometric information, at least one progressive volume growth profile of the injection moulded part (18) in the filling direction of the mould cavity (16) is calculated, and taking into consideration the progressive volume growth profile at least one injection process is calculated, a simplified, fast and effective parameterisation of the injection moulding machine is made possible, the operator is relieved by the implemented expert knowledge and the quality of the injection moulded part (18) is improved.

### CROSS REFERENCE TO RELATED APPLICATIONS

The present application refers to and claims the priority of the German patent application 10 2018 123 361.2, filed on Sep. 23, 2018, the disclosure content of which is herein incorporated by reference in its entirety.

### TECHNICAL FIELD

The disclosure relates to a method for controlling a machine for processing plastics and other plasticisable materials such as ceramic or powder materials.

### BACKGROUND

In order to perform an injection molding procedure successfully, as well as appropriate hardware there is also a need for extensive knowledge of the injection molding procedure, or how the injection molding procedure is to be carried out for the desired molding so that the highest possible quality can be achieved in an efficient cycle time. Frequently, for this numerous complex adjustments have to be made to the injection molding machine itself, to the mold, to the peripherals or to the machine controller, and these are associated with considerable work and may result in errors. Moreover, adjustments of this kind are frequently based on empirical values, with the result that the complex control and adjustment of the injection molding procedure is usually the preserve of only skilled operating personnel who know how to make these adjustments on the basis of their specialized knowledge and experience. Otherwise, the adjustments have to be arrived at by trial and error, a time-consuming and labor-intensive procedure.

WO 2014/183863 A1, which forms the basis of the preamble of claim 1, discloses a method for operating a machine for processing plastics, for which information on a component shape of a molding is provided to the controller of the machine, and plant and process parameters are calculated by the controller for the purpose of manufacturing the molding. A plurality of wizards for quality, injection mold and molding is used to check whether the desired molding is manufacturable using the calculated plant and process parameters. If the molding is not manufacturable with these, this is displayed to the operating person, who is prompted to specify further information.

AT 513481 A4 discloses a simulation device and a method in which, in a machine simulation, an injection molding machine is simulated and a first parameter, which is communicated to a procedure simulation for the purpose of simulating an injection molding material and/or an injection mold, is calculated. The attempt is thus made to calculate the finished product of the injection molding procedure in advance. For the result of the injection molding procedure, essential elements of the procedure are simulated and the results of the simulations are exchanged in order to calculate the finished product in advance.

A method for simulating a hypothetical configuration of a shaping facility is disclosed in DE 10 2015 015 811 A1. A process value that is measured during operation of the shaping facility is read off and used as an input parameter for a model that represents the hypothetical configuration of the shaping facility. In this way, it is possible even at a preliminary stage to clarify whether a change to the existing shaping facility in respect of optional equipment is beneficial on a case-by-case basis. Thus, the complete shaping facility is simulated, or its behavior is simulated, if a change is made for example to the peripherals.

DE 692 15 634 T2 discloses a method for monitoring the injection pressure of an injection molding machine during an injection molding procedure. Cavity data for the injection mold are stored in advance, and these are displayed in a subsequent step, in subdivided regions. In a subsequent step, the screw position is determined, and a graph showing a relationship between the determined screw position and the input pressure is displayed. The screw position region, which corresponds to the subdivided regions of the cavity, which is filled with synthetic resin, is moreover displayed, and from this it is clear which screw position is adopted with which filling level of the cavity.

A method for monitoring a resin position in a mold interior during an injection molding procedure is disclosed in DE 692 18 317 T2. Here, the mold interior is subdivided into a multiplicity of regions having boundary portions. Then, volumes are distributed over these subdivided regions and input to a control unit such that, in a subsequent step, screw positions in which the front end of the resin reaches the boundary portions can be displayed.

In the solutions of the prior art, either on the one hand the complete molding or on the other the complete shaping facility is simulated, for either of which appropriate simulation or processing power is required. Further, with these solutions the operating person has to enter many inputs, of the most diverse kinds, in respect of the simulation parameters. When the molding is subsequently produced, these inputs obtained from the simulation have to be applied again for the actual injection molding procedure.

### BRIEF DESCRIPTION

The disclosure enables simplified, rapid and effective parameterization of the injection molding procedure and thus to improve the set-up time and quality of the molding.

This is achieved with a method for controlling a machine for processing plastics and other plasticisable materials such as powder and/or ceramic materials

In the method according to the disclosure, the greatest possible amount of adjustment data of the injection molding procedure is calculated for an injection molding machine and its peripherals in respect of the material to be processed, from the known three-dimensional model of the molding. The machine has a mold opening and closing unit, for opening and closing an injection mold comprising at least one mold cavity for manufacturing a molding that corresponds to the shape of the mold cavity, an injection molding unit comprising devices for plasticising and for injecting the plasticisable material into the mold cavity, and a machine controller that is in communication with an expert knowledge unit and is operable by the operating person, where necessary by way of interactive contact, for example by way of a display/operating device. The display/operating device takes the form for example of an interactive input facility having a screen, for example in the form of a multi-touch screen, and is in communication with the machine controller. The expert knowledge unit may for example be in the form of databases and/or data memories that are in communication with the machine controller for example by way of a network.

The expert knowledge unit contains for example data on materials, such as the specific density of the solid and fluid material, the melting point, the flow index, the maximum shear rate and/or in general the pressure/temperature behavior as the materials cool from fluid to solid. However, it is also possible for it to contain further data in respect of the materials to be processed.

A further database relates for example to data for carrying out the method, and is built up from knowledge of injection molding in relation to characteristic process sequences. An example of this is provided by data for the filling time for particular classes of mold, particular flow path/wall thickness ratios in the molding with particular classes of mold, and holding pressures in relation to minimum and maximum wall thicknesses of the molding.

A further database contains for example knowledge of the machine controller in relation to the static and dynamic properties of the kinematics of the particular machine.

For the method according to the disclosure, information on the geometry of the molding and/or the mold cavity and the sprue point is provided to the machine controller. This information may be input to the machine controller directly by way of a data carrier, for example, by the operating person, or may be selected by way of interfaces between the machine and CAD data servers. The starting point is therefore a geometric three-dimensional model of the molding per se, so the result of the injection molding procedure parameterization depends substantially on the specific geometric information about the molding. Moreover, at least one step-by-step volume growth profile of the molding is calculated from the geometric information, wherein for an advantageously rapid and simple calculation the volume growth profile of the molding is calculated layer by layer, beginning from at least one sprue point, with a particular distance (Δs) covered by a conveying device or a particular volume (ΔV) being associated with each layer. The sprue point may be selected interactively by the operating person, preferably from the displayed geometric data at the operating unit of the injection molding machine, or alternatively may be stored parametrically in the geometric data or calculated by a geometric analysis with an additionally known mold geometry. The molding is divided up into layers, in a manner similar for example to additive manufacturing. Adding up the respective volume of all the layers gives the complete volume of the molding.

Taking into account volume growth profile, at least one injection procedure is further calculated. This makes it possible to parameterize the injection molding procedure at the injection molding machine rapidly, effectively and in a simplified manner, since there is no need for particular specialist knowledge when the machine is set up. Rather, the operating person is supported in setting up, with the result that possible sources of error have already been eliminated at the start of the injection molding procedure, with the result that on the one hand the mold proving procedure is made substantially shorter, and it is less prone to error in respect of possible underfilling or overfilling, and the quality of the molding is improved by the fact that the volume growth profile is adapted to the geometry. At the same time, the expert knowledge required for operation of the machine can be reduced.

It is essential, for calculating the step-by-step volume growth profile, that information is provided on at least some of the information comprising the geometry of the molding and/or the mold cavity and the sprue geometry. This information may come from different sources. For example from a CAD program or a 3D scan. In principle, it is also conceivable for the information to be available already, for example in the expert knowledge unit.

At least one volume growth profile of the molding is then calculated, taking into account the geometric information. For this, the geometry of the molding in the direction of filling is divided up into regions that, taken together, give the complete volume of the molding. Thus, each region contains a corresponding part volume. When the mold cavity is filled, the regions are filled progressively, wherein in general sometimes a relatively large volume, and at others a relatively small one, is filled with material until all the regions or the complete volume are completely filled. As a result of this process, a volume growth profile is calculated.

The volume growth profile is calculated in the first step by means of a preferably constant virtual digitalization filling volume. On this basis, the possible successive step is for example that the volume growth profile is presented as a curve of the volume over time or over distance, for example that covered by a conveying device such as a conveying screw. Using the volume growth profile from the geometric data of the molding, adjustment data in respect for example of the injection volume, the wall thicknesses, the flow ratios, the flow velocities and the absolute flow paths can be derived.

Taking into account the volume growth profile, at least one setpoint parameterization for an injection curve of the injection molding machine is then calculated. The filling curve calculated in this way is displayed, for example as a suggestion, to the operating person at an interactively operable display/operating device.

Calculation of the step-by-step volume growth profile of the molding is preferably performed before a first injection procedure for manufacture of a molding is carried out. As a result, possible error sources can be reliably eliminated at the beginning of the injection molding procedure, and the molding proving procedure can be further shortened. At the same time, the expert knowledge required for operation of the machine can be reduced to an even greater extent.

Further, for an advantageous efficient calculation, the layer-by-layer calculation of the volume growth profile is carried out with the same volume step each time. For example, for each layer step, a projected surface is calculated from the geometric data of the molding, and if the volume step is known a function is calculated by adding up the surfaces multiplied by the volume step, from which the volume growth profile is calculated.

Preferably he volume growth profile is calculated taking into account at least one of the items of information in respect of the total injection volume or the thickest and thinnest wall thickness of the molding or the wall thickness ratios or flow path ratios. This information is preferably to be found in the expert knowledge. Using these parameters, known in the art of injection molding, a volume growth profile can be generated rapidly and in a manner that is readily reproducible by the operating person.

Particularly preferably, for the purpose of calculating the volume growth profile information from the expert knowledge unit is used, this information being classified into groups in order to achieve faster access to the desired information. Here, it is also possible for classification into groups to be performed such that it is reproducible by the operating person—that is, the person can also interactively and rapidly access relevant supporting information. Such criteria include for example mold classes for injection molds, filling times during the injection procedure for manufacturing the molding, flow path/wall thickness ratios in the molding, mold classes or indeed holding pressures, in relation to minimum and maximum wall thicknesses in the molding. The classifier may also advantageously perform this classification into groups interactively with an operating person, with reference to these criteria.

In principle, interactive control with an operating person is always advantageous, since in that case the system can prompt the person operating it for further input, or also inform them of the results obtained, if there are for example malfunctions, if information is missing, or even if the result is that a volume growth profile of this kind is not performable, or not performable in that way, on the machine in question.

For an advantageously high degree of accuracy at the same time as rapid calculation, the volume growth profile is calculated by at least one integration method, for example by a numerical integration method such as the trapezoidal rule.

For an advantageously simple, intuitive operation, the geometric data that are input are displayed at the display/operating device. In a further step, at least one sprue point is identified in relation to the axis of injection. This can be performed for example interactively, by the operating person, but preferably the machine controller recognizes it automatically as a result of a corresponding analysis of the geometric data, in particular if there is bounding geometric information about the mold, for example by means of a search for bounding volumes that are not closed. Further, symmetry characteristics are identified, such as whether the system is a multiple-cavity system that may be supplied by a hot-runner system, and/or whether there is a sprue distributor system having multiple sprues. Depending on the case, the method first considers only one cavity and thereafter calculates the number of further cavities, by adding up or by an offset. In the case of multiple sprues, for example each individual sprue point is considered separately and added on until a contiguous volume composed of the different sprue points is reached. As soon as the material fronts are in contact, further consideration is carried out as though there were only one sprue point. In respect of any dynamic pressure losses, a cross sectional area is for example added up. This procedure simplifies the processor operations and so saves time and makes operation more direct.

It is advantageous for efficient adjustment of the machine and any peripherals that material information on the material to be processed is provided to the machine controller as information predetermined by the operating person, and/or selected by the operating person from an expert knowledge unit. In principle, it is conceivable for example to select the material class or the exact material desired. With this, and with machine component data such as data on the installed injection module/screw, any plasticization models provided for these for different screw geometries from the expert knowledge unit, for example, and/or any data on peripherals, it is possible to derive adjustment data for example for the screw speed, back pressure and temperature adjustment for the cylinder heating and mold temperature control.

At least one injection procedure is calculated using the volume growth profile and the material information. The volume growth profile makes it possible to know how much volume is to be filled for how long or over what path. If this is combined with the material information, it is advantageously possible to calculate adjustment data for example in respect of the injection profile, the injection speed, the holding pressure and/or the holding pressure time.

Preferably the setpoint parameterization for the injection curve is also determined on the assumption of a material front that flows at constant speed.

In order advantageously to ensure that an injection molding procedure is reliable and efficient, the injection curve is adapted by means of parameters delimiting the injection molding unit. For example, first the maximum speeds of the machine are taken into account and selected such that the machine is not overdriven. Then, for example the accelerations of the machine are taken into account such that the maximum accelerations are not exceeded. Moreover, the injection molding procedure is standardized to give absolute physical values, by analyzing the minimum and maximum flow path lengths, wall thickness ratios and total part volume by a class similarity comparison in the expert knowledge unit, preferably for example being adapted to the absolute minimum or maximum filling time that is typical of that class.

Further advantages are apparent from the subclaims and the description below of a preferred exemplary embodiment. The features listed individually in the claims are combinable, where this is technologically meaningful, and may be supplemented by explanatory information from the description and details from the Figures, further variant embodiments of the disclosure being pointed out.

### BRIEF DESCRIPTION OF THE FIGURES

The disclosure is explained in more detail below with reference to an exemplary embodiment represented in the attached Figures, in which:

FIG. 1 shows a schematic illustration of an injection molding machine and associated machine controller with a display/operating device,

FIG. 2 shows a flow chart for control and parameterization of the machine,

FIG. 3a shows a schematic illustration of a molding, with sprue,

FIG. 3b shows a schematic illustration of a molding, with sprue, and

FIG. 4 shows the display/operating device with volume growth profile and parameter input.

### DETAILED DESCRIPTION

The disclosure is now explained in more detail by way of example, with reference to the attached drawings. However, the exemplary embodiments are only examples, which are not intended to restrict the inventive concept to a particular arrangement. Before the disclosure is described in detail it should be pointed out that it is not restricted to the respective structural parts of the device and the respective method steps, since these structural parts and methods may vary. The terms used here are merely intended to describe particular embodiments and are not used restrictively. Moreover, where the singular or the indefinite article is used in the description or the claims, this also refers to a plurality of these elements unless the overall context unambiguously indicates otherwise.

In the context of the disclosure, the following definitions are used:
A “volume growth profile” describes the increase in volume over time or over the path of a conveying device.
An “injection procedure” is the procedure required for manufacture of a particular molding of which the geometric data form the basis for calculating the volume growth profile.
A parameterized “injection curve” is an injection procedure that is determined by parameters calculated using the method and that makes it possible to manufacture the particular molding on the respective injection molding machine, using the machine controller.

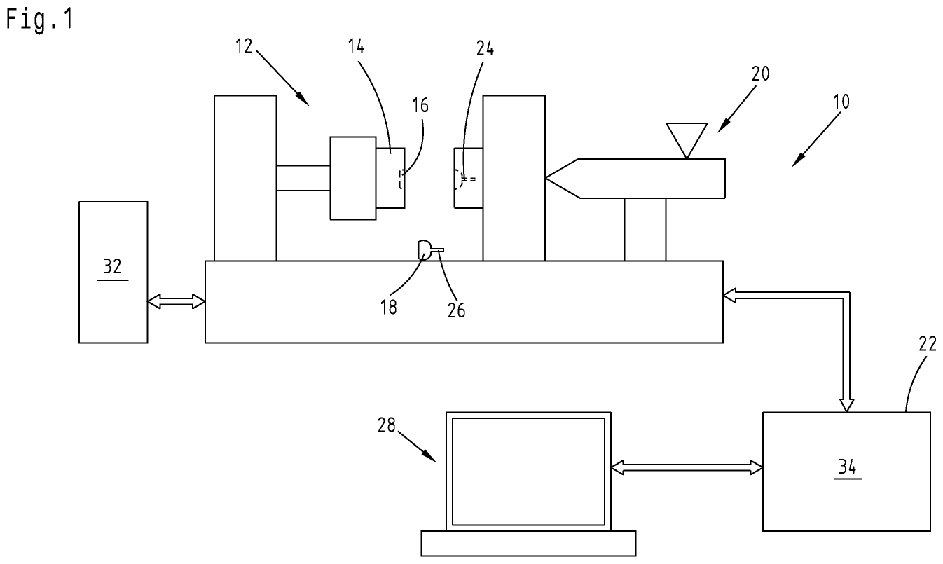

FIG. 1 shows a schematic illustration of a machine 10 for processing plastics and other plasticisable materials such as ceramic or powder materials. The machine 10 has a mold opening and closing unit 12, for opening and closing an injection mold 14 having at least one mold cavity 16 for manufacturing a molding 18 that corresponds to the shape of the mold cavity 16, and an injection molding unit 20. In FIG. 1, the injection mold 14 is shown open, and the molding 18 has been ejected from the mold cavity 16, where appropriate with its sprue 26. Plasticisable material is supplied to the mold cavity 16 by way of a sprue geometry 24. Any peripherals 32, such as cooling devices or removal devices, are connected to the machine 10 and/or the machine controller 22.

Associated with the machine 10 is a machine controller 22 that is in communication by way of networks, for example, with an expert knowledge unit 34 in the form of for example databases.

The expert knowledge unit 34 comprises for example data in relation to materials to be processed, such as the specific density of the solid and fluid material, the melting point, the flow index, the maximum shear rate and/or in general the pressure/temperature behavior as the materials cool from fluid to solid, data in relation to injection molding knowledge on characteristic process sequences, such as data for the filling time for particular classes of mold, in conjunction with flow path/wall thickness ratios in the molding, coupled with particular classes of mold, and holding pressures in relation to minimum and maximum wall thicknesses of the molding and/or data on the static and dynamic properties of the kinematics of the machine. In principle, however, there may also be other data in the expert knowledge unit 34, which may serve to describe an injection molding procedure, the associated equipment and/or materials. In principle, it is also conceivable for the expert knowledge unit 34 to be in the machine controller 22 itself.

For interactive contact between the machine controller 22 and the operating person, a display/operating device 28 is provided, which takes the form for example of a screen with keyboard, a (multi-)touch screen or indeed other suitable devices such as voice input.

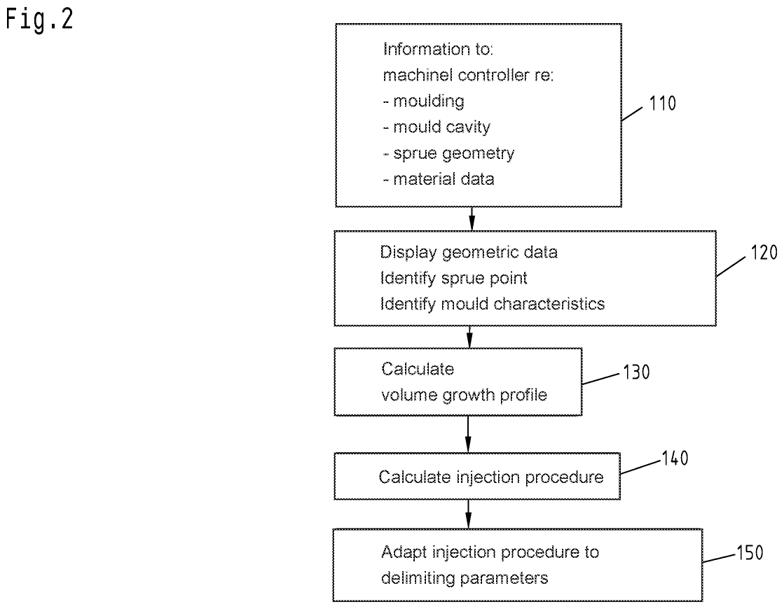

FIG. 2 shows the sequence of the method. At the start of the method, in step 110, the machine controller 22 receives information on the geometry of the molding 18 and its arrangement, as the mold cavity 16 in the mold and the sprue geometry 24. The geometric data may come from the most diverse sources, for example a CAD program or a 3D scan of a 3D prototype printed beforehand, for example. In principle, it is also conceivable for the expert knowledge unit 34 already to contain geometric data and/or for these to be stored or storable there.

Preferably, in a further exemplary embodiment, in step 110 material data on the material to be processed are provided, which the operating person for example predetermines or selects from the expert knowledge unit 34. For example, a material class or the exact material are selected from a material database of the expert knowledge unit 34. The machine controller 22 uses this and machine component data, such as the installed injection and plasticising module/screw, any plasticization models available for this purpose for different screw geometries, and any data on the peripherals 32, to calculate adjustment values for the machine 10, such as the screw speed, back pressure and temperature adjustment for the cylinder heating and mold temperature control.

Preferably, in step 120 the geometric data of the molding 18 are displayed at the display/operating device 28. This allows the operating person to identify, simply and intuitively, at least one sprue point in relation to the axis of injection. In principle, it is also conceivable for the machine controller 22 to calculate a suggestion for the sprue point, for example on the basis of knowledge of the geometric relationship between the cavity system and the mold. Further interactive operations by the operating person are preferably identifying mold characteristics, such as whether the mold is a multiple-cavity mold with a hot-runner system or a mold with multiple sprues. Depending on the case, the method first considers only one cavity and thereafter calculates the number of further cavities, by simple adding up or by an offset. In the case of multiple sprues, each individual sprue point is considered separately and added on until a contiguous volume composed of the different sprue points is reached. As soon as the material fronts are in contact, further consideration is carried out as though there were only one sprue point. In respect of any dynamic pressure losses, a cross sectional area is for example added.

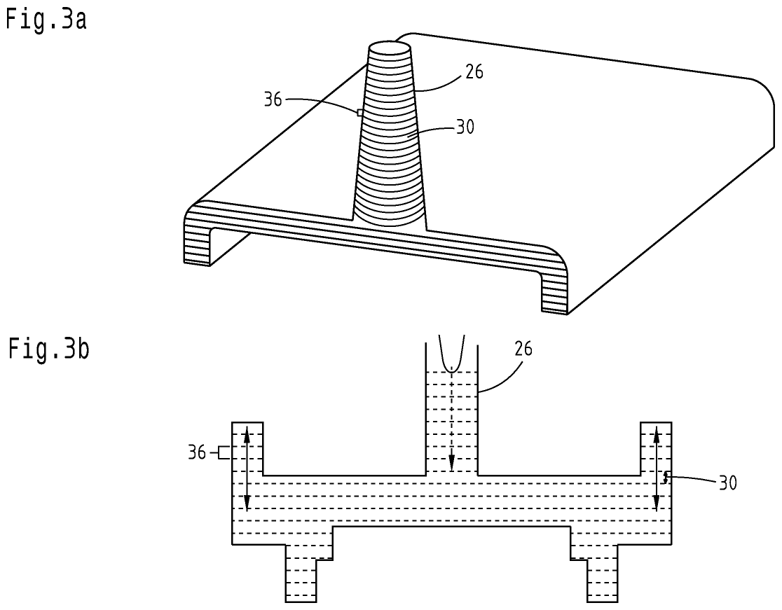

The volume growth profile is calculated in step 130. FIGS. 3a and 3b schematically show geometries of moldings 18. With the aid of the geometric data of the molding 18, the volume growth profile is calculated layer by layer, beginning at a sprue point. The geometry of the molding 18 is built up layer by layer, or step by step. For example, in FIG. 3a the volume of the molding 18 is built up, beginning at the sprue point, in layers 36 until it reaches the base of the molding. Then build-up continues radially in relation to the sprue point 26. In FIG. 3b, beginning at the sprue point 26, both sides—to left and right of the sprue point 26—are built up evenly.

It has shown to be advantageous to perform the calculation of the step-by-step volume growth profile of the molding before a first injection procedure for manufacture of a molding is carried out. As a result, possible sources of error can be reliably eliminated at the start of the injection procedure, and the molding proving procedure can be further shortened. At the same time, the expert knowledge required for operating the machine can be reduced to an even greater extent.

Preferably, the layer-by-layer calculation of the volume growth profile is carried out in each case with the same volume step 30, according to FIGS. 3a and 3b.

Further preferably, the volume growth profile is calculated by at least one integration method, for example by a numerical integration method such as the trapezoidal rule.

To generate the volume growth profile, there can be used information comprising the total injection volume or the thickest and thinnest wall thicknesses of the molding or the wall thickness ratios or flow path ratios, wherein this information is preferably to be found in the expert knowledge unit.

In order to make calculation of the volume growth profile reproducible and where appropriate to make it faster, it is possible to utilize a classifier, which uses and classifies information from the expert knowledge unit and/or information predetermined by the operating person. This information may be categorized into classes and distinguished, for example by at least one of the following criteria:
Mold classes for injection molds,
filling time classes, during the injection procedure for manufacturing the molding 18,
flow path/wall thickness ratios in the molding 18,
material classes,
holding pressures in relation to minimum and maximum wall thicknesses in the molding 18.

The classifier, preferably interactively with an operating person, classifies the molding 18 on the basis of these criteria in order to make relevant information from the expert knowledge unit accessible for the purpose of calculation.

To mention only a few non-restrictive examples, it is thus possible for selection classes to be for example different wall thickness flow ratios of for example more than 200, or maximum filling times of for example less than 0.2 s.

In step 140, on the assumption of a material front that flows at constant speed, preferably at least one injection procedure is calculated.

Preferably, the volume growth profile of the molding 18 is calculated layer by layer, preferably beginning from at least one sprue point, wherein a particular distance Δs covered by a conveying device such as a conveying screw, or a particular volume ΔV, is associated with each layer 36.

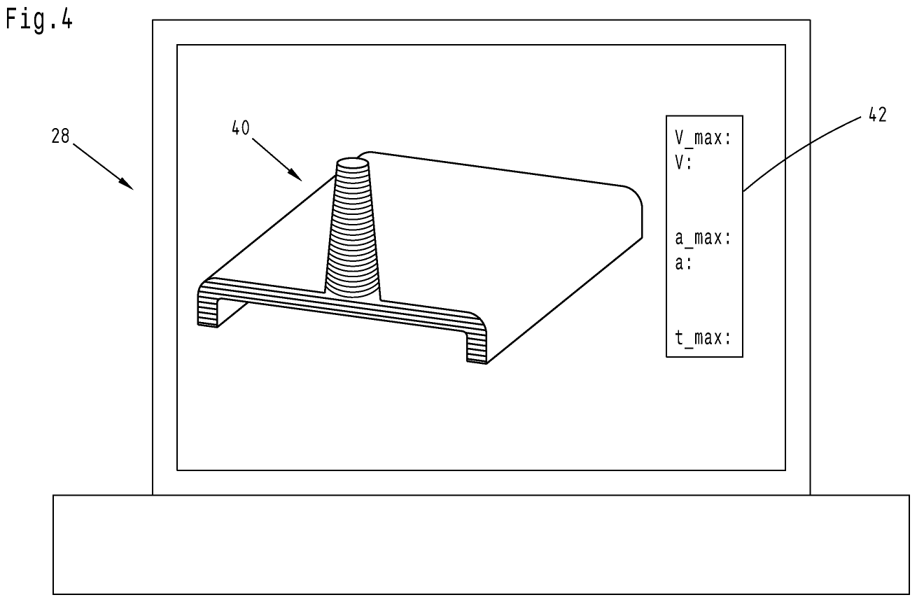

In a further preferred exemplary embodiment, in step 150 the injection procedure is adapted by parameters 42 delimiting the injection molding unit 20, such as maximum speeds and/or accelerations at which the machine 10 can be operated so that the machine 10 is not overdriven. Further, the minimum/maximum desired filling time is adapted using for example a quadratic or sinusoidal interpolation of the speed values possible for the machine, for example by a recursive method. The parameters 42 can be adapted, for example according to FIG. 4, by the operating person at the display/operating device 28.

In principle, interactive control with an operating person is always advantageous, since in that case the system can prompt the person operating it for further input, or also inform them of the results obtained, if there are for example malfunctions, if information is missing, or even if the result is that a volume growth profile of this kind is not performable, or not performable in that way, on the machine in question. Likewise, the operating person can intervene in a targeted manner, for example to identify a sprue point or direction of flow.

It is self-evident that this description can be subject to a great variety of modifications, amendments and adaptations, which belong within the scope of equivalents to the accompanying claims.

1.-10. (canceled)

11. A method for controlling a machine for processing plastics and other plasticisable materials, wherein the machine comprises
a mold opening and closing unit configured for opening and closing an injection mold comprising at least one mold cavity configured for manufacturing a molding that corresponds to the shape of the at least one mold cavity,
an injection molding unit configured for plasticising and for injecting a plasticisable material into the at least one mold cavity,
a machine controller that is in communication with an expert knowledge and is configurable to be interactively influenced by an operating person,
wherein the method comprises the steps of:
providing geometric information, on at least one of the geometry of the molding or the geometry of the mold cavity that receives the molding, to the machine controller,
providing information on the sprue geometry to the machine controller,
calculating at least one step-by-step volume growth profile of the molding in the direction of filling the mold cavity, taking into account the geometric information, wherein the volume growth profile of the molding is calculated layer by layer, beginning from at least one sprue point, wherein a particular distance covered by a conveying device, or a particular volume, is associated with each layer,
wherein the calculation of the at least one step-by-step volume growth profile of the molding is performed before a first injection procedure for manufacture of a molding is carried out,
wherein the volume growth profile is calculated taking into account at least one of the items of information in respect of the total injection volume or the thickest and thinnest wall thickness of the molding or the wall thickness ratios or flow path ratios, and wherein
at least one injection procedure is calculated, taking into account the step-by-step volume growth profile and on an assumption of a material front that flows at constant speed.

12. A method according to claim 11, wherein the at least one of the items of information is to be found in the expert knowledge.

13. A method according to claim 11, wherein the calculation of the volume growth profile is carried out with the same volume step each time.

14. A method according to claim 11, wherein for calculating the volume growth profile, information from the expert knowledge is categorized into classes and distinguishable by at least one of the following criteria:
mold classes for injection molds,
filling time classes during the injection procedure for manufacturing the molding,
flow path/wall thickness ratios in the molding,
material classes,
holding pressures in relation to minimum and maximum wall thicknesses in the molding,
wherein a classifier classifies the molding on the basis of these criteria in order to make information from the expert knowledge accessible for the purpose of calculation.

15. A method according to claim 14, wherein the classifier classifies the molding interactively with an operating person.

16. A method according to claim 11, wherein the volume growth profile is calculated by at least one integration method.

17. A method according to claim 11, comprising at least one of the steps of:
displaying the geometric data at a display/operating device,
identifying at least one sprue point in relation to an axis of injection,
identifying mold characteristics.

18. A method according to claim 17, wherein the identifying at least one sprue point in relation to an axis of injection is conducted with reference to a display.

19. A method according to claim 11, wherein material information on the material to be processed is provided to the machine controller as a further information, at least one of predetermined by the operating person or selected as information from the expert knowledge, and is used for standardizing the volume growth profile, and wherein the at least one injection procedure is calculated taking into account the material information.

20. A method according to claim 11, wherein at least one setpoint parameterization for an injection curve is determined on the assumption of a material front that flows at a flow front speed that is as constant as possible.

21. A method according to claim 20, wherein the at least one setpoint parameterization is determined on the assumption of the material front flowing at a constant volume growth rate.

22. A method according to claim 11, wherein a setpoint parameterization for an injection curve is adapted to parameters delimiting the injection molding unit.
